(19) United States
(12) Patent Application Publication
(10) Pub. No.: US 2025/0211255 A1
(43) Pub. Date: Jun. 26, 2025

(54) HIGH-THROUGHPUT LOW-POWER DECODER

(71) Applicants: Furkan Ercan, Medford, MA (US); Deepak Dasalukunte, Beaverton, OR (US)

(72) Inventors: Furkan Ercan, Medford, MA (US); Deepak Dasalukunte, Beaverton, OR (US)

(21) Appl. No.: 18/394,282

(22) Filed: Dec. 22, 2023

(51) Int. Cl. H03M 13/15

(52) U.S. Cl. CPC H03M 13/1575

(57) ABSTRACT

A decoder device can include an input to provide a stream of data elements to a data decoding pipeline. The device can further include an early termination element coupled at a coupling point of one or more of the input or at a pipeline stage of the data decoding pipeline. The early termination element can remove a data element from the stream at the respective coupling point based on a determination that the data element is to be removed from the stream. The early termination element can further provide the removed data element to output circuitry of the decoder device. Other methods and apparatuses are described.

### TECHNICAL FIELD

Embodiments pertain to communications, and more specifically to decoders within communication receivers.

### BACKGROUND

Decoder circuitry is used in most modern communication systems, including optical or satellite communication systems, as well as in memory/storage applications and other applications. Design tradeoffs are often made in decoder design. For example, high throughput often comes at the cost of high power consumption. There is a general need for a decoder that can provide high throughput, without high power consumption.

### BRIEF DESCRIPTION OF THE DRAWINGS

FIG. 1 is a block diagram of a communication system that can include decoders in accordance with some aspects.

FIG. 2 is a first example decoder system in accordance with some aspects.

FIG. 3 is a second example decoder system in accordance with some aspects.

FIG. 4 is a third example decoder system in accordance with some aspects.

FIG. 5 illustrates a decoding method according to some aspects.

### DETAILED DESCRIPTION

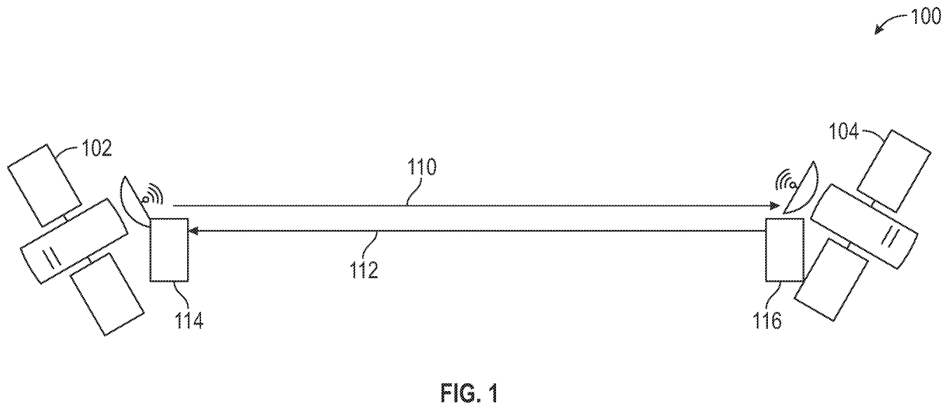

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims. Systems in which methods and algorithms can be implemented are discussed with reference to FIG. 1.

FIG. 1 is a block diagram of a communication system that can include decoders in accordance with some aspects. The system 100 can include two or more communicating devices 102, 104, shown as satellites in the example although aspects of the disclosure are not limited thereto. While two devices 102, 104 are shown, the communication system 100 can include any number of devices, such as satellites or any other device capable of optical or other communication.

The devices 102, 104 may also include a command and data handling system and multiple power sources. Each device 102, 104 can communicate with other devices (e.g., each other or other devices not shown in FIG. 1) over respective links 110, 112. For example, the device 102 can send data to the device 104 over link 110 and can receive data from the device 104 over the link 112. Links 110, 112 can also be to other devices not shown in FIG. 1, e.g., in a relay or mesh arrangement. Links can use optical signals to communicate between the devices 102, 104.

Transceiver circuitry 114, 116 (e.g., optical transceivers although aspects are not limited thereto) can be provided on each side of the links 110, 112. Each of transceiver circuitry 114, 116 can include encoders and decoders. Decoders can include forward error-correction (FEC) modules, and these can introduce throughput bottlenecks. However, there are different tradeoffs and design choices to be made if throughput is to be increased.

FEC filters received data from the undesired impacts of the imperfect communication medium, regarded as the noise without loss of generality. Examples of these impacts include errors, erasures, or fading, and the errors can occur at the bit-level, symbol-level, or packet level.

Various communication standards define the type of FEC codes that should be used at their physical layer implementation. Some standards include Low-Density Parity-Check (LDPC) codes, Polar codes, Reed-Solomon (RS) codes, Bose-Chaudhuri-Hocquenghem (BCH) codes, and Cyclic Redundancy Check (CRC) codes. Decoders for these codes typically implement dedicated algorithms. For example, LDPC decoders use dedicated Belief Propagation decoders such as scaled min-sum algorithm. Polar decoders use a binary tree traversal search architecture, such as Successive Cancellation List/Flip algorithms. RS decoders use a syndrome calculator, followed by a symbol-level Key Equation Solver such as the Berlekamp-Massey algorithm. (Binary) BCH decoders use a simplified, bit-level version of the RS decoding procedure. CRC uses a single Linear-Feedback Shift Register (LFSR) to derive a remainder.

The distinct decoding algorithms for each class of code lead to dedicated hardware implementations for these decoders. When these algorithms are incorporated in hardware, design decisions are made before implementation in a physical device, depending on the target application. For example, for applications that favor low power than any other metric, (e.g., battery-operated Internet of Things (IOT) sensors used in massive machine-type communications (mMTC) scenarios), compact designs that take up minimal area and power overhead are preferred.

For applications that promote high throughput, such as Ultra High Definition (UHD) video streaming devices under enhanced mobile broadband (eMBB) use cases, algorithm unfolding in time (pipelining) and space (parallelization of processing elements) are considered during design time.

For applications that demand absolute low latency, such as real-time streaming or autonomous vehicle (V2X) communications within the Ultra-Reliable Low-Latency Communications (URLLC) use cases, any of the techniques described above can be used depending on the power/throughput budget of the application. Although the above use cases are defined under cellular communications standards, any of the aspects and tradeoffs thereof described herein can be applied to any communication application, and FEC architectures can and should be tuned for any communication scenario.

Architectural choices for any of the above scenarios (or other scenarios not described), can include pipelining, parallelization, early termination, and compact design. Pipelining favors throughput but comes at the cost of massive power consumption, in addition to using up a lot of area, which makes it impractical for most applications. Parallelization (e.g., adding many decoders in parallel) is similar to pipelining in these respects. Early termination involves taking early terminated outputs away from a pipeline but can introduce latency. Compact design uses up less power than pipelining and parallelization but can add latency and decrease throughput. Apparatuses and systems according to aspects of the disclosure address these concerns by reducing power consumption for pipelined decoder architectures.

Aspects of the present disclosure provide a low-power pipelined implementation that takes advantage of early termination of the decoding algorithm in at least two ways. The early terminated outputs are taken away from the pipeline and stored at a separate memory block, introducing idle time to pipeline even when a codeword is inputted at each defined period. In return, decoders according to aspects described herein provide an opportunity to clock gate the pipeline stages that are inactive. At typical channel conditions, where codewords do not require intense decoding, the power consumption is minimized, leading to a low-power solution while keeping all the high-throughput benefits of the pipelined approach.

In real-time decoding (e.g., livestreaming), the received order of the packets cannot be reordered. Therefore, packets that are impacted more severely by the noise take more time in the decoder framework, stalling the frames that follow and increasing overall latency. To minimize or eliminate latency, therefore, pipelining is used in the examples described below according to aspects of this disclosure.

Example aspects provide early termination possibilities. Other available architectures that target lower latency typically do not implement early termination. However, some example aspects provide pipeline exits for early termination, wherein terminated packets are put on hold at an accompanying memory block. The memory block according to aspects of the disclosure use FIFO-like implementations, although aspects of the disclosure are not limited to any particular memory logic. The memory block shall be able to hold S (or S-1) individual packets for a pipelined decoder that has S stages. This approach greatly reduces the activity factor of the pipeline, which is a major contributor to overall power consumption. The held packets are accompanied by a controller that keeps track of their ordering and can release them promptly upon completion of the preceding packet in the pipeline.

To further minimize the impact of the power consumption caused by pipelining, clock gating is applied to each stage of the pipeline. The enable signal of a pipeline stage is prompted by the activity of the preceding stage. Because early terminated packets are handled separately in a power-efficient way, we enable the possibility of having idle pipeline stages despite traditional unfolded approaches.

For packets that can be reordered at the receiver side, such as receiving fractures of packets for a large file, the architecture according to aspects of the present disclosure can minimize the latency overhead primarily caused by the packets that are heavily impacted by the noise. In this context, if the pipeline stages can hold the entire codeword, then the memory FIFO block may not be required. Instead, the pipeline registers can be used to temporarily store the early terminated codewords. This way, the delay caused by a problematic frame is overlapped by rescheduled packets that are decoded at a shorter duration. In return, the time that systems would go without providing an output would decrease, leading to a reduced experienced latency.

The clock gating can be run by a global signal that can reduce power consumption by placing decoders or other aspects of the circuitry described herein, in a rest or idle state. Any decoders that allow possibility of early termination can implement aspects of the present disclosure.

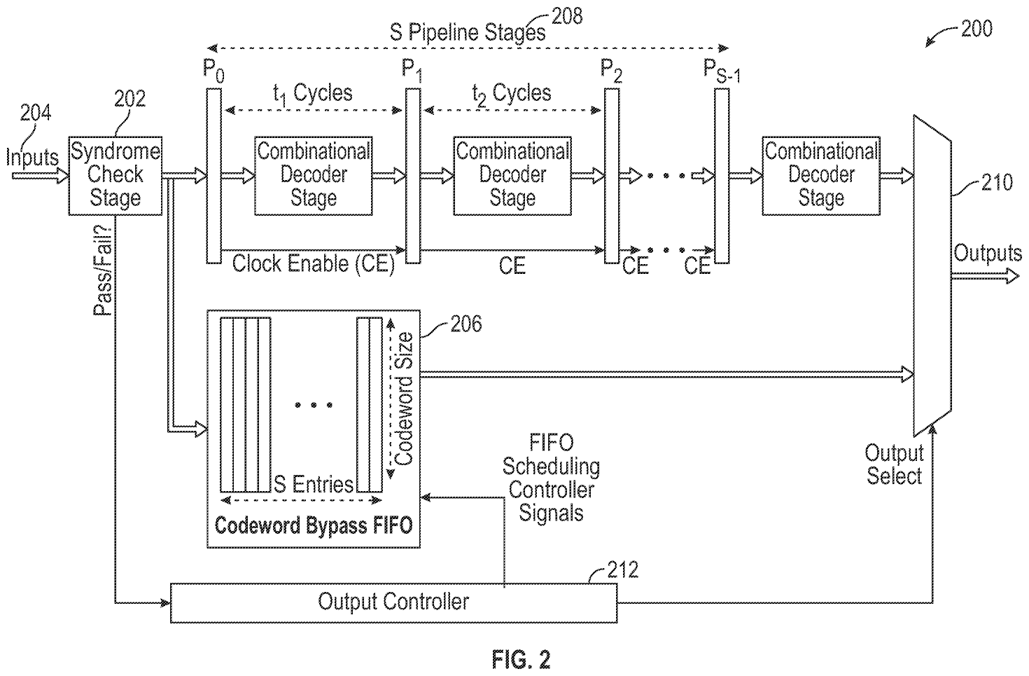

FIG. 2 is a first example decoder system 200 according to some aspects of the disclosure. In system 200, a syndrome computation unit 202 can act as an early termination element and be coupled (at a coupling point) to receive inputs 204. The decoder system 200 can comprise or be a component of a communication device including at least one communication interface to receive data.

The syndrome computation unit 202 can check whether the received inputs 204 (e.g., codewords) are impacted by noise. Unless the impact of the noise lands the codeword to another valid codeword in the codebook, which is extremely unlikely for a well-designed code, an all-zero syndrome result indicates a codeword successfully recovered. Therefore, the syndrome computation unit 202 can determine that decoding can be terminated early, and further stages (e.g., Pₒ-P_{S-1}) need not to be activated (e.g., data elements can be removed and provided directly from syndrome computation unit 202 to FIFO 206 or other buffer). The syndrome computation unit 202 output can be forwarded to the FIFO 206 to secure a block, until the preceding codeword is decoded, if there is any. Otherwise stages of the pipeline 208 can be executed according to pipeline architectures. Each pipeline stage (e.g., Pₒ-P_{S-1}) can be activated by a clock enable signal originated from the preceding stage. Output is provided to multiplexer 210, either by a final pipeline stage or by FIFO 206. Output controller 212 can control input and output from FIFO 206. For example, output controller 212 can include a state machine to input and output from FIFO. The output controller 212 can also control output selection from the multiplexer 210. The output controller 212 can disable respective pipeline stages from which the data elements were removed (and stored in FIFO 206 or other buffer).

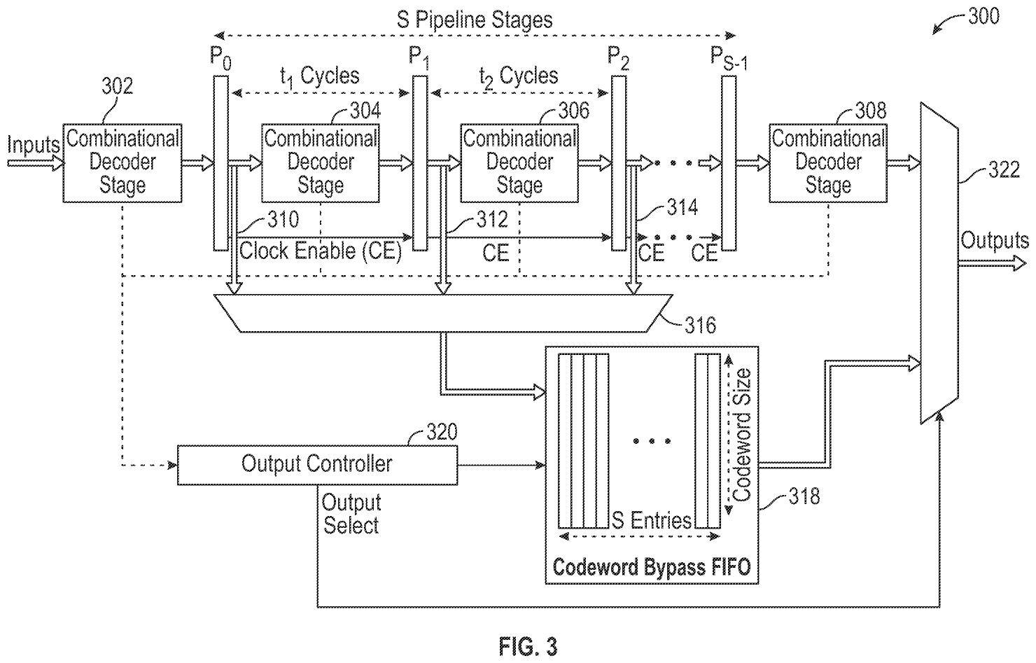

FIG. 3 is a second example decoder system 300 in accordance with some aspects. The decoder system 300 can comprise or be a component of a communication device including at least one communication interface to receive data. In system 300, iterative FEC decoders 302, 304, 306, 308 are provided with early termination (e.g., early termination elements can be provided within, or as part of pipeline stages) by decision circuitry or an element coupled at a coupling point within or outside of pipeline stages P₀P_{S-1}wherein pipeline stage Po can be considered upstream from pipeline stage P_{S-1}and pipeline stage P_{S-1} can be considered downstream from pipeline stage P₀. In system 300, some or all stages of the pipeline (e.g., stages P₀P_{S-1}) can produce a final output 310, 312, 314. The finalized outputs are collected by a MUX 316 that is activated by an early termination signal (provided e.g., by elements of the pipeline stages or other circuitry not shown), and the MUX 316 select is driven by the pipeline stage (e.g., a respective one of stages P₀P_{S-1}). In case two or more pipeline stages provide an output simultaneously, two strategies can be derived. For the first strategy, extra registers can hold the produced outputs. However, this approach is faulty, because if the same pipeline exit would be used by another codeword that exists in the pipeline while the dedicated register is full, errors will arise. The second strategy is to ‘halt’ the pipeline for one cycle if there are two or more valid outputs at the same time, and flush one output to the FIFO 318 at a time until there is one valid codeword left in the pipeline. Then the pipeline would be ‘unhalted’ and continue processing while the last one valid codeword is being flushed into the FIFO 318.

A similar output controller 320 and output MUX 322 can be provided as described with respect to system 200. The output controller 320 can input the codeword information from each stage and controls the bypass FIFO 318 as well as the output MUX 322. The output controller 320 can disable respective pipeline stages from which the data elements were removed (and stored in FIFO 318 or other buffer).

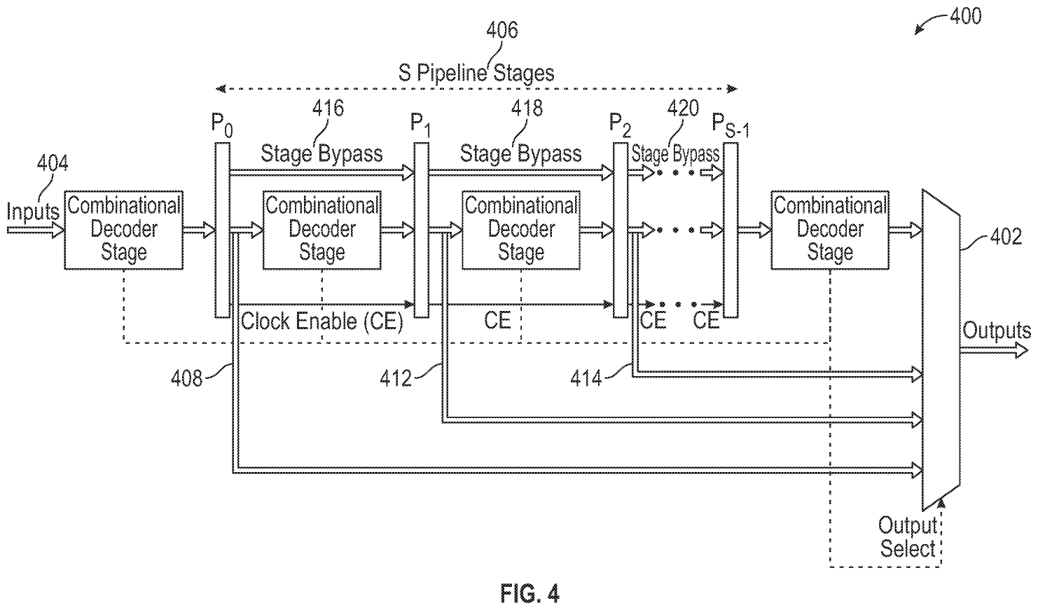

FIG. 4 is a third example decoder system 400 in accordance with some aspects. The decoder system 400 can comprise or be a component of a communication device including at least one communication interface to receive data. Decoder system 400 provides a reordering-enabled pipelined architecture with no bypass FIFO. In this model, reordering of the received frames are enabled, meaning the received frames do not have to be output from the decoder system 400 at MUX 402 in the same order that the frames are received at input 404.

Because ordering of packets is not needed in decoder system 400 there is not a need for a bypass FIFO as in systems 200, 300. The pipeline stages 406 can hold the early terminated codeword outputs 408, 412, 414 which can be bypassed to the output MUX 402. In case multiple stages of the pipeline generate outputs simultaneously, then a priority can be applied at the output MUX 402. In order not to halt decoding during such a corner case, bypass logic in between pipelined stages can be established, wherein stage bypass logic 416, 418, 420 can be enabled when more than one final codeword are available in the decoder system 400 to skip or bypass any respective pipeline stage/s (e.g., to pass data through at least one pipeline stage without pipelining the respective data).

Aspects of this disclosure provide error correcting code decoder circuitry that provides high-speed throughput while dissipating minimal power consumption. The circuitry that leverages the early termination logic can also be used as an attachment to any pipeline-based early termination-available FEC decoder. Pipeline stages can be clock-gated by preceding stages, and a separate FIFO memory lane that stores codewords can be provided.

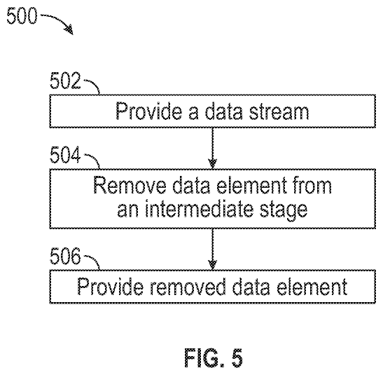

FIG. 5 illustrates a decoding method 500 according to some aspects. Reference is made to components of FIGS. 1-4 when describing operations of method 500. Decoding method 500 can be controlled within syndrome checks or circuitry within pipeline stages, output controllers, or other components of decoder systems 100, 200, 300 and 400.

At operation 502, a device (e.g., communication circuitry or component of any of devices 102, 104 (FIG. 1) can provide a stream of data elements to a data decoding pipeline (e.g., any pipelines described above with reference to FIG. 2-4).

The method 500 can continue with operation 504 with removing a data element from the stream at a respective coupling point based on a determination that the data element is to be removed from the stream. For example, coupling points can be part of or subsequent to syndrome checks or within or after pipeline phases as described earlier herein.

The method 500 can continue with operation 506 with providing the removed data element to output circuitry (e.g., MUX outputs as described above). Prior to being output, the removed elements can be stored in buffer/s e.g., FIFO as controlled by output controllers.

Algorithmic logic circuitry for the embodiments described herein is a circuit or combination of circuits to perform the computational execution of the algorithms used to determine the optimum bias setting on the photodiodes. This processing includes but is not limited to the adaptive filter for example the LMS engine or other adaptive filter alternative implemented in dedicated logic or executed with a software framework in microprocessor core.

### ADDITIONAL DESCRIPTION AND EXAMPLES

These several embodiments and examples can be combined using any permutation or combination. The Abstract is provided to allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

Example 1 is a decoder device comprising: an input to provide a stream of data elements to a data decoding pipeline; and an early termination element coupled at a coupling point of one or more of the input or at a pipeline stage of the data decoding pipeline, the early termination element configured to: remove a data element from the stream at the respective coupling point based on a determination that the data element is to be removed from the stream; and provide the removed data element to output circuitry of the decoder device.

In Example 2, the subject matter of Example 1 can optionally include a buffer for storing removed data elements.

In Example 3, the subject matter of Example 2 can optionally comprise wherein an early termination element is provided at least at one pipeline stage and wherein the early termination element is configured to provide the removed data element to the buffer.

In Example 4, the subject matter of Example 3 can optionally include wherein the early termination element comprises a syndrome check circuit coupled at the input, and wherein the syndrome check element is configured to provide the removed data element to the buffer.

In Example 5, the subject matter of Example 4 can optionally include stage bypass circuitry configured to pass data through at least one pipeline stage without pipelining the respective data.

In Example 6, the subject matter of Example 2 can optionally include an output controller configured to control inputs to the buffer and to provide data elements stored in the buffer to the output circuitry, and to disable respective pipeline stages from which the data elements were removed and stored in the buffer.

In Example 7, the subject matter of Example 2 can optionally include wherein the buffer is a first in first out (FIFO) buffer.

Example 8 is as method for decoding comprising: providing a stream of data elements to a data decoding pipeline; removing a data element from the stream at a respective coupling point based on a determination that the data element is to be removed from the stream; and providing the removed data element to output circuitry.

In Example 9, the subject matter of Example 8 can optionally include storing removed data elements.

In Example 10, the subject matter of Example 9 can optionally include checking data at an input and providing removed data elements directly from the input to a buffer.

In Example 11, the subject matter of Example 9 can optionally include wherein removing is performed at a pipeline element downstream from an input.

In Example 12, the subject matter of Example 9 can optionally include controlling inputs to a buffer in a first in first out fashion.

In Example 13, the subject matter of Example 12 can optionally include passing data through at least one pipeline stage without pipelining the respective data.

Example 14 is a communication device comprising: at least one communication interface to receive data; and transceiver circuitry coupled to the communication interface, the transceiver circuitry including a decoder device comprising: an input interface to provide a stream of data elements to a data decoding pipeline; an early termination element coupled at a coupling point of one or more of the input interface or at a pipeline stage of the data decoding pipeline, the early termination element configured to: remove a data element from the stream at the respective coupling point based on a determination that the data element is to be removed from the stream; and provide the removed data element to output circuitry of the decoder device.

In Example 15, the subject matter of Example 14 can optionally include a buffer for storing removed data elements.

In Example 16, the subject matter of Example 15 can optionally include wherein an early termination element is provided at least at pipeline stage and wherein the early termination element is configured to provide the removed data element to the buffer.

In Example 17, the subject matter of Example 16 can optionally include wherein the early termination element comprises a syndrome check circuit coupled at the input interface, and wherein the syndrome check element is configured to provide the removed data element to the buffer.

In Example 18, the subject matter of Example 17 can optionally include stage bypass circuitry configured to pass data through at least one pipeline stage without pipelining the respective data.

In Example 19, the subject matter of Example 14 can optionally include comprising an output controller configured to: control inputs to a buffer; and provide data elements stored in the buffer to the output circuitry.

In Example 20, the subject matter of Example 19 can optionally include wherein the output controller is further configured to disable respective pipeline stages from which the data elements were removed and stored in the buffer.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A decoder device comprising:
an input to provide a stream of data elements to a data decoding pipeline; and
an early termination element coupled at a coupling point of one or more of the input or at a pipeline stage of the data decoding pipeline, the early termination element configured to:
remove a data element from the stream at the respective coupling point based on a determination that the data element is to be removed from the stream; and
provide the removed data element to output circuitry of the decoder device.

2. The decoder device of claim 1, further comprising a buffer for storing removed data elements.

3. The decoder device of claim 2, wherein an early termination element is provided at least at one pipeline stage and wherein the early termination element is configured to provide the removed data element to the buffer.

4. The decoder device of claim 3 wherein the early termination element comprises a syndrome check circuit coupled at the input, and wherein the syndrome check element is configured to provide the removed data element to the buffer.

5. The decoder device of claim 4, comprising stage bypass circuitry configured to pass data through at least one pipeline stage without pipelining the respective data.

6. The decoder device of claim 2, further comprising an output controller configured to control inputs to the buffer and to provide data elements stored in the buffer to the output circuitry, and to disable respective pipeline stages from which the data elements were removed and stored in the buffer.

7. The decoder device of claim 2, wherein the buffer is a first in first out (FIFO) buffer.

8. A method for decoding, the method comprising:
providing a stream of data elements to a data decoding pipeline;
removing a data element from the stream at a respective coupling point based on a determination that the data element is to be removed from the stream; and
providing the removed data element to output circuitry.

9. The method of claim 8, further comprising storing removed data elements.

10. The method of claim 9, further comprising checking data at an input and providing removed data elements directly from the input to a buffer.

11. The method of claim 9, wherein removing is performed at a pipeline element downstream from an input.

12. The method of claim 9, further comprising controlling inputs to a buffer in a first in first out fashion.

13. The method of claim 12, further comprising passing data through at least one pipeline stage without pipelining the respective data.

14. A communication device including:
at least one communication interface to receive data; and transceiver circuitry coupled to the communication interface, the transceiver circuitry including a decoder device comprising:
an input interface to provide a stream of data elements to a data decoding pipeline;
an early termination element coupled at a coupling point of one or more of the input interface or at a pipeline stage of the data decoding pipeline, the early termination element configured to:
remove a data element from the stream at the respective coupling point based on a determination that the data element is to be removed from the stream; and
provide the removed data element to output circuitry of the decoder device.

15. The communication device of claim 14, further comprising a buffer for storing removed data elements.

16. The communication device of claim 15, wherein an early termination element is provided at least at pipeline stage and wherein the early termination element is configured to provide the removed data element to the buffer.

17. The communication device of claim 16, wherein the early termination element comprises a syndrome check circuit coupled at the input interface, and wherein the syndrome check element is configured to provide the removed data element to the buffer.

18. The communication device of claim 17, comprising stage bypass circuitry configured to pass data through at least one pipeline stage without pipelining the respective data.

19. The communication device of claim 14, further comprising an output controller configured to:
control inputs to a buffer; and
provide data elements stored in the buffer to the output circuitry.

20. The communication device of claim 19 wherein the output controller is further configured to disable respective pipeline stages from which the data elements were removed and stored in the buffer.
